(19) United States
(12) Patent Application Publication
(10) Pub. No.: US 2012/0223896 A1
(43) Pub. Date: Sep. 6, 2012

(54) TOUCH DISPLAY APPARATUS HAVING COVER LENS STRUCTURE

(75) Inventors: Chien-Hsiang Tseng, New Taipei City (TW); Ke-Chin Chang, New Taipei City (TW); Chia-Feng Teng, New Taipei City (TW)

(73) Assignee: HANNSTAR DISPLAY CORPORATION, New Taipei City (TW)

(21) Appl. No.: 13/369,305

(22) Filed: Feb. 9, 2012

(30) Foreign Application Priority Data
Mar. 3, 2011 (TW) 100107190

(51) Int. Cl. G06F 3/041; H05K 7/00

(52) U.S. Cl. 345/173; 361/679.01

(57) ABSTRACT

A touch display apparatus having a cover lens structure is described. The touch display apparatus includes a touch sensing layer, a display panel adjacent to the touch sensing layer, a backlight module adjacent o the display panel and a cover lens structure. The cover lens structure includes a substrate, a first segment height and a side-wall portion. The first segment height protrudes from the substrate wherein the first segment height and the substrate forms a first receiving space to allow the first segment height to retain the touch sensing layer. The side-wall portion extends and bends from a side edge of the substrate wherein the side-wall portion has a locking portion for buckling the backlight module.

### FIELD OF THE INVENTION

The present invention relates to a display apparatus having a cover, and more particularly relates to a touch display apparatus having a cover lens structure.

### BACKGROUND OF THE INVENTION

Currently, with the rapid development of the information technology, touch technique is widely applicable to a variety of electronic devices having display panels for inputting the message to these electronic devices. The user can easily read and browse the information on the display units or transmits the inputted messages by the electronic devices if the user touches the display panels with the finger or stylus pen. Such the inputting manner of the message or information replaces the keypad or keyboard used in the conventional electronic device. For example, since iPhone, a registered trademark of Apple Corporation, is increasingly popular in today's mobile phone market, touch screen attracts a great of attention of the manufacturers. In order to increase the contact durability of the touch screen, the cover lens is formed by glass material. However, disadvantageously, the glass material is hard to machine or polish and thus increases manufacturing cost. Further, the weight of the glass material is greater than that of the plastic material to decrease the portability of electronic device. Moreover, the cover lens with the glass material is fabricated in high temperature process so that the shape of cover lens is usually flat but not an irregular shape.

Additionally, many component layers such as a cover lens, a touch sensing layer and a display panel in a conventional touch screen are sequentially adhered together by glue. Specifically, it is required to change or adjust the arrangement sequence of the component layers when assembling these component layers. Such the situation makes the circuit elements on the touch sensing layer and display panel fall off if the circuit elements are attached to the glue. That is, the touch sensing layer and display panel are damaged so that the touch screen are reworked and the manufacturing efficiency is reduced. Consequently, there is a need to develop a display apparatus with cover lens to solve the aforementioned problems.

### SUMMARY OF THE INVENTION

One objective of the present invention is to provide a touch display apparatus having a cover lens structure. The touch display apparatus includes one or more segment height for embedding and locating component layers such as touch sensing layer and display panel therein. The above manner can improve the glue applied to the conventional component layers to save the manufacturing cost of the touch display apparatus, solve the problems of reworking process, and increase the manufacturing efficiency.

Another objective of the present invention is to provide a touch display apparatus having a cover lens structure. The touch display apparatus includes one or more segment height for embedding and locating component layers such as touch sensing layer and display panel therein. The above manner can improve the machining characteristic of the cover lens structure and effectively reduce the weight of touch display apparatus for portability.

According to the above objectives, the present invention sets forth a touch display apparatus having a cover lens structure. The cover lens structure protects the touch display apparatus from damage wherein the touch display apparatus further includes a touch sensing layer, a display panel and a backlight module. The cover lens structure further includes a substrate, a first segment height and a side-wall portion. The first segment height protrudes from the substrate wherein the first segment height and the substrate forms a first receiving space to allow the first segment height to retain the touch sensing layer. The side-wall portion extends and bends from a side edge of the substrate wherein the side-wall portion has a locking portion for buckling the backlight module. The cover lens structure further includes a second segment height protruding from the first segment height wherein the second segment height and the first segment height form a second receiving space to allow the second segment height to retain the display panel.

In another embodiment, the touch display apparatus includes a touch sensing layer, a display panel adjacent to the touch sensing layer, a backlight module adjacent to the display panel, and a cover lens structure. The cover lens structure further includes a substrate, a first segment height and a side-wall portion. The first segment height protrudes from the substrate wherein the first segment height and the substrate forms a first receiving space to allow the first segment height to retain the touch sensing layer. The side-wall portion extends and bends from a side edge of the substrate wherein the side-wall portion has a locking portion for buckling the backlight module. The cover lens structure further includes a second segment height protruding from the first segment height wherein the second segment height and the first segment height form a second receiving space to allow the second segment height to retain the display panel.

In the present invention, the touch display apparatus includes one or more segment height for embedding and locating component layers therein. It improves the glue for assembling the conventional component layers to save the manufacturing cost of the touch display apparatus, solve the problems of reworking process, and increase the manufacturing efficiency.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic three-dimensional exploded view of a touch display apparatus according to one embodiment of the present invention;

FIG. 2A is a schematic top view of the touch display apparatus according to a first embodiment of the present invention;

FIG. 2B is a schematic cross-sectional view and a local enlarged view of the touch display apparatus having a cover lens structure in FIG. 2A along the line A-A′ according to one embodiment of the present invention;

FIG. 3A is a schematic top view of the touch display apparatus according to a second embodiment of the present invention;

FIG. 3B is a schematic cross-sectional view and a local enlarged view of the touch display apparatus having a cover lens structure in FIG. 3A along the line B-B′ according to one embodiment of the present invention;

FIG. 4A is a schematic top view of the touch display apparatus disposed in a housing base according to one embodiment of the present invention; and

FIG. 4B is a schematic cross-sectional view and a local enlarged view of the touch display apparatus in FIG. 4A along the line C-C′ according to one embodiment of the present invention.

### DETAILED DESCRIPTION OF THE PREFERRED EMBODIMENTS

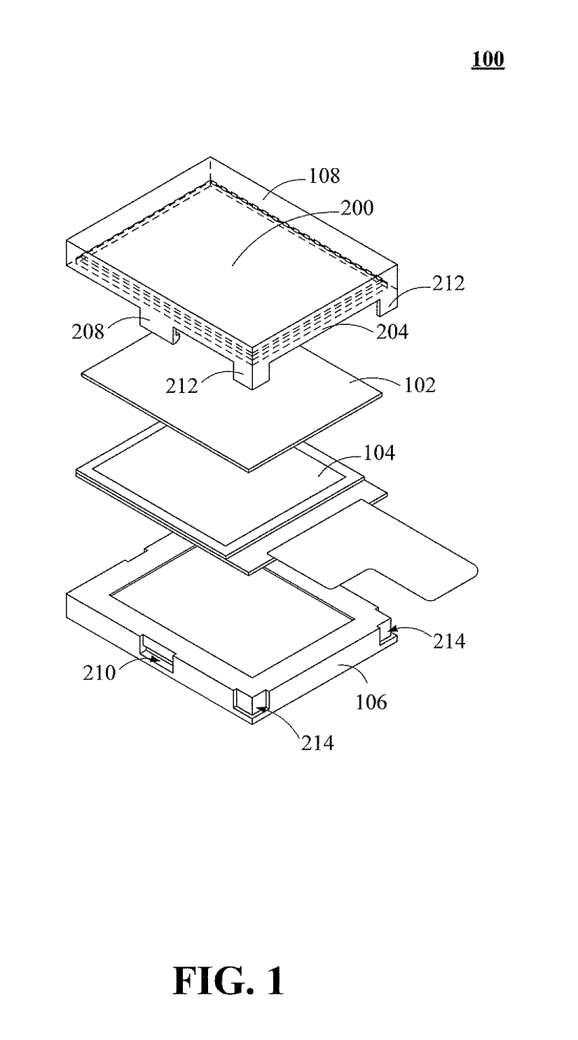

FIG. 1 is a schematic three-dimensional exploded view of a touch display apparatus 100 according to one embodiment of the present invention. The touch display apparatus 100 includes a touch sensing layer 102, a display panel 104, a backlight module 106 and a cover lens structure 108. The touch sensing layer 102 is disposed between the display panel 104 and the cover lens structure 108 for detecting a sensing signal. The display panel 104 is adjacent to the touch sensing layer 102. When the user contacts the cover lens structure 108, the touch sensing layer 102 detects the sensing signal and display the message associated with user contact on the display panel 104. The backlight module 106 is disposed under the display panel 104 for providing the display panel 104 with the light to show the message. The cover lens structure 108 can protects the touch sensing layer 102, the display panel 104 and the backlight module 106 from damage. After completing the assembly of touch display apparatus 100, the cover lens structure 108 is capable of stably securing the touch sensing layer 102 and display panel 104 which are disposed between the cover lens structure 108 and the backlight module 106 by combining the cover lens structure 108 and the backlight module 106. Besides the cover lens structure 108 is applicable to the touch display apparatus 100, the cover lens structure 108 can be used in liquid crystal display (LCD) and other type of display devices.

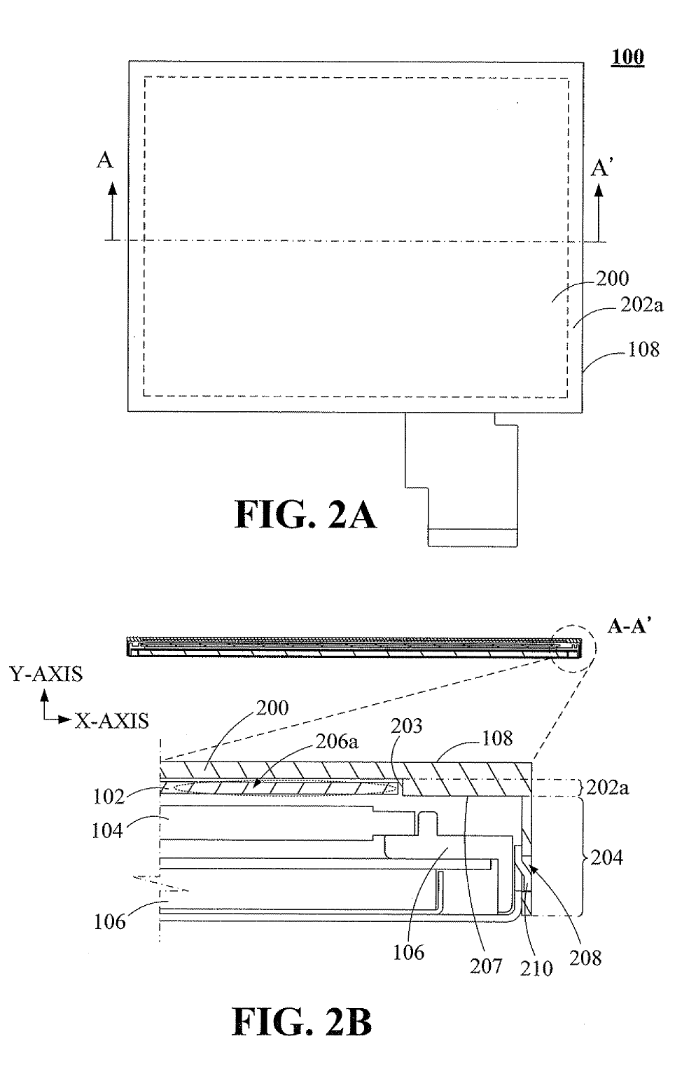

Please refer to FIG. 2A and FIG. 2B. FIG. 2A is a schematic top view of the touch display apparatus 100 according to a first embodiment of the present invention. FIG. 2B is a schematic cross-sectional view and a local enlarged view of the touch display apparatus 100 having a cover lens structure 108 in FIG. 2A along the line A-A′ according to one embodiment of the present invention. The cover lens structure 108 further includes a substrate 200, a first segment height 202a and a side-wall portion 204. The first segment height 202a protrudes from the substrate 200 wherein the first segment height 202a and the substrate 200 forms a first receiving space 206a so that the first segment height 202a retains the touch sensing layer 102. That is, a lateral surface 203 of the first segment height 202a and a partial surface of the substrate 200 construct the first receiving space 206a for retaining the touch sensing layer 102. Specifically, the lateral surface 203 of the first segment height 202a contacts and retains the edge of the touch sensing layer 102. Thus, the touch sensing layer 102 is embedded in the first receiving space 206a of the first segment height 202a so that the movement of the touch sensing layer 102 along X-axis and Y-axis is restricted to the first receiving space 206a to prevent the touch sensing layer 102 from releasing. The material of the cover lens structure 108 is transparent plastic selected one group consisting of polycarbonate (hereinafter PC) and polymethyl methacrylate (hereinafter PMMA) to reduce the manufacturing cost. In one preferred embodiment, an injection molding process is used to form the substrate 200, the first segment height 202a and the side-wall portion 204 of the cover lens structure 108. That is, the substrate 200, the first segment height 202a and the side-wall portion 204 are integrally formed to improve the machining characteristic of the cover lens structure 108. Further, the touch sensing layer 102 may be an irregular shape.

As shown in FIG. 2A and FIG. 2B, the first segment height 202a is an annular structure such as a rectangular shape, a square shape, or an irregular shape constructed on the substrate 200. The first segment height 202a further includes a first end-surface 207 adjacent to the first receiving space 206a for contacting the display panel 104 such that the first segment height 202a retains the display panel 104. In another case, a clearance is disposed between the first end-surface 207 and the display panel 104 so that the cover lens structure 108 is combined with the backlight module 106.

The side-wall portion 204 extends and bends from the side edge of the substrate 200 and the side-wall portion 204 has a locking portion 208 for buckling a fastening portion 210 of the backlight module 106. In one embodiment, the locking portion 208 is a buckling opening and the fastening portion 210 is a hook to be fastened to the buckling opening, as shown in FIG. 2B. In another embodiment, the locking portion 208 is a hook and the fastening portion 210 is a cavity (shown in FIG. 1) to be fastened to the hook (shown in FIG. 1). The side-wall portion 204 further includes a position extrusion 212 from an edge of the side-wall portion 204 for locating into a recess region 214, as shown in FIG. 1.

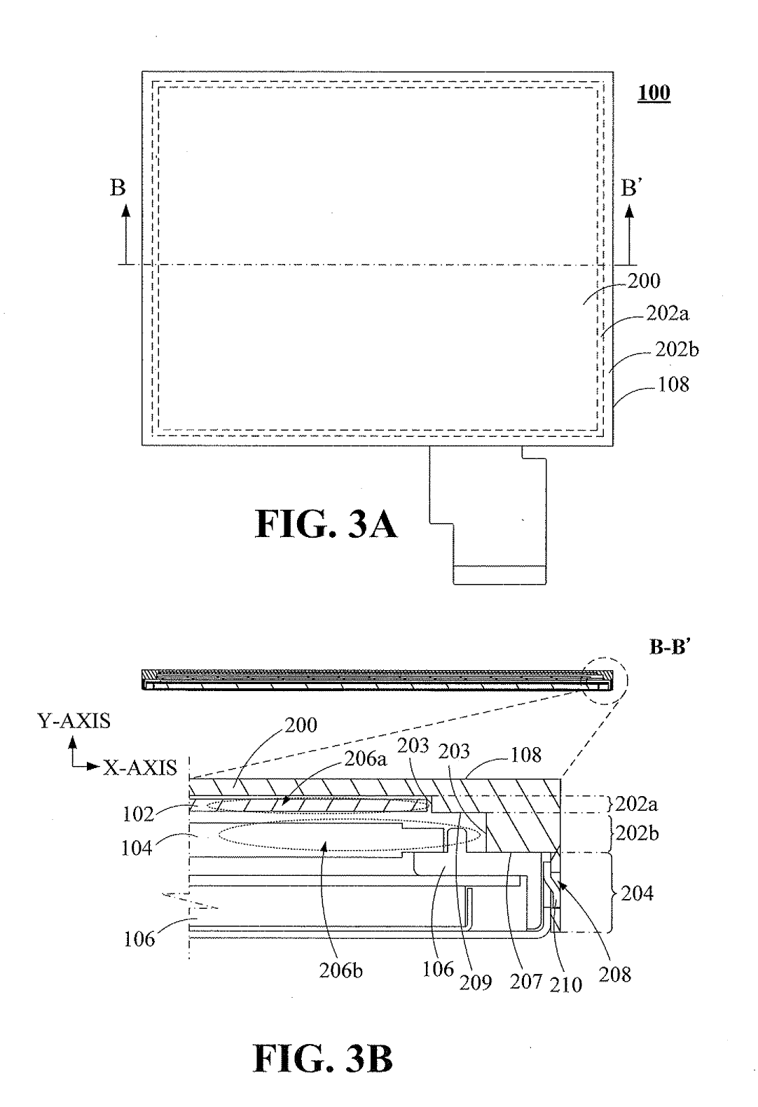

Please refer to FIG. 3A and FIG. 3B. FIG. 3A is a schematic top view of the touch display apparatus 100 according to a second embodiment of the present invention. FIG. 3B is a schematic cross-sectional view and a local enlarged view of the touch display apparatus 100 having a cover lens structure 108 in FIG. 3A along the line B-B′ according to one embodiment of the present invention. The cover lens structure 108 in FIG. 3A and FIG. 3B is similar to the cover lens structure 108 in FIG. 2A and FIG. 2B. The difference is that the cover lens structure 108 in FIG. 2A and FIG. 2B further includes a second segment height 202b protruding from the first segment height 202a wherein the second segment height 202b and the first segment height 202a form a second receiving space 206b so that the second segment height 202b retains the display panel 104. That is, a lateral surface 203 of the second segment height 202b and the side-wall portion 204 construct the second receiving space 206b for retaining the display panel 104. Specifically, the lateral surface 203 of the second segment height 202b contacts and retains the edge of the display panel 104. Thus, the display panel 104 is embedded in the second receiving space 206b of the second segment height 202b so that the movement of the display panel 104 along X-axis and Y-axis is restricted to the second receiving space 206b to prevent the display panel 104 from releasing. The material of cover lens structure 108 is transparent plastic selected one group consisting of polycarbonate (hereinafter PC) and polymethyl methacrylate (hereinafter PMMA) to reduce the manufacturing cost. In one preferred embodiment, an injection molding process is used to form the substrate 200, the first segment height 202a, the second segment height 202b and the side-wall portion 204 of the cover lens structure 108. That is, the substrate 200, the first segment height 202a, the second segment height 202b and the side-wall portion 204 are integrally formed. As shown in FIG. 3A and FIG. 3B, the second segment height 202b is an annular structure such as a rectangular shape, a square shape, or an irregular shape constructed on the substrate 200. The second segment height 202b further includes a second end-surface 209 adjacent to the second receiving space 206b for contacting the backlight module 106 such that the second segment height 202b is capable of retaining backlight module 106. In another case, a clearance is disposed between the second end-surface 209 and the backlight module 106 so that the cover lens structure 108 is combined with the backlight module 106.

Specifically, as shown in FIGS. 2A, 2B, 3A, and 3B, the cover lens structure 108 forms segment heights with various profiles therein to receive the touch sensing layer 102 and display panel 104 for retention so that the touch sensing layer 102 and display panel 104 are embedded respectively in the first receiving space 206a and the second receiving space 206b constructed by the first segment height 202a and the second segment height 202b for retaining the touch sensing layer 102 and display panel 104. In comparison with conventional the touch sensing layer and a display panel adhered to the cover lens by glue, the cover lens structure 108 in the present invention is formed by structural assembly, an embedding manner and positioning fabrication for retention to improve the usage of glue in the prior art. Moreover, if there is a position deviation between the cover lens, the touch sensing layer and the display panel, it is required to assemble the cover lens, the touch sensing layer and the display panel. However, the glue may damages the surface and circuit components on the touch sensing layer and the display panel while assembling. Advantageously, the touch sensing layer 102 and the display panel 104 in the present invention can be easily removed from the first receiving space 206a and the second receiving space 206b constructed by the first segment height 202a and/or the second segment height 202b to prevent reworking and repeated assembly and to increase the manufacturing efficiency.

In addition, while assembling the touch display apparatus 100 by stacking component layers, the display panel, touch sensing layer and cover lens are sequentially placed on the backlight module by applying the glue. However, it is necessary to locate prior component layer in advance before next one is placed. For example, before the touch sensing layer adheres to the display panel, the display panel is attached to the backlight module and then the cover lens is assembled with the touch sensing layer. The above assembly manner is too complicated. On the contrary, the touch sensing layer 102 is retained in the first segment height 202a and/or one side of the display panel 104 is retained in the second segment height 202b and the other side of the display panel 104 is attached to the backlight module 106. Afterwards, the retained assembly including the touch sensing layer 102, the first segment height 202a and/or one side of the display panel 104 is combined with the attached assembly including the other side of the display panel 104 and the backlight module 106, which can be assembled with different assembly sequence. Therefore, assembly flexibility facilitates fabrication process to improve the manufacturing efficiency of the touch display apparatus 100.

It should be noted that the cover lens structure 108 in the present invention may include more than two segment height for retaining various component layers with different area. In other words, each of the receiving space constructed by the segment height substantially is equal to each component layer area to allow each component layer to be inserted into the corresponding to the corresponding receiving space. The structure of each segment height is similar to the first segment height 202a and the second segment height 202b.

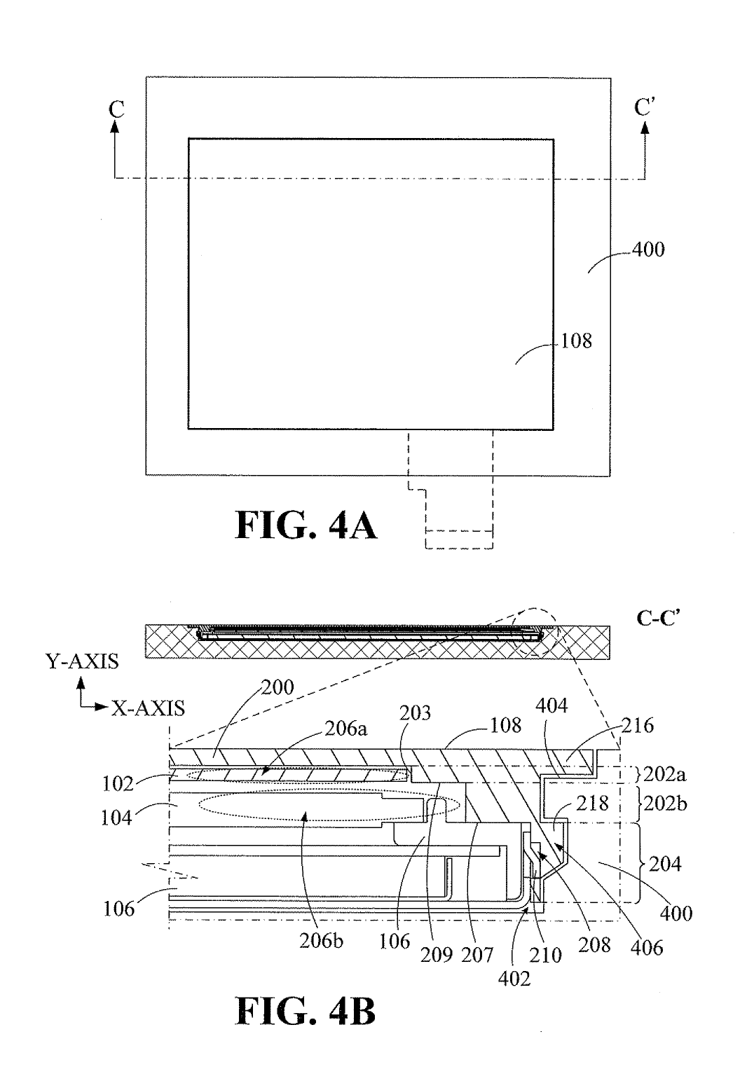

Please see FIG. 4A and FIG. 4B. FIG. 4A is a schematic top view of the touch display apparatus 100 disposed in a housing 400 according to one embodiment of the present invention. FIG. 4B is a schematic cross-sectional view and a local enlarged view of the touch display apparatus 100 in FIG. 4A along the line C-C′ according to one embodiment of the present invention.

The cover lens structure 108 of the touch display apparatus 100 further includes a supporting portion 216 and a clasping portion 218. The supporting portion 216 extends from the circumference of the cover lens structure 108 outwards. The clasping portion 21.8 is disposed under the supporting portion 216 and extrudes from the circumference of the cover lens structure 108 outwards. The housing 400 further includes a containing space 402, a base unit 404 and a clasping recess 406. The base unit 404 is disposed in the wall of the housing 400 for receiving the supporting portion 216 correspondingly. The clasping recess 406 is disposed in the wall of the containing space 402 and under the base unit 404 to be clasped in the clasping portion 218. When the touch display apparatus 100 is disposed in the housing 400, the containing space 402 of the housing 400 contains the touch display apparatus 100 wherein the base unit 404 of the housing 400 supports the supporting portion 216 of the cover lens structure 108 and the clasping recess 406 of housing 400 clasps the clasping portion 218 of the cover lens structure 108.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A cover lens structure for protecting a touch display apparatus from damage, wherein the touch display apparatus further comprises a touch sensing layer, a display panel and a backlight module, the cover lens structure comprising:
a substrate;
a first segment height protruding from the substrate wherein the first segment height and the substrate forms a first receiving space to allow the first segment height to retain the touch sensing layer; and
a side-wall portion extending and bending from a side edge of the substrate wherein the side-wall portion has a locking portion for buckling the backlight module.

2. The cover lens structure of claim 1, wherein the first segment height further comprises a first end-surface adjacent to the first receiving space for contacting the display panel.

3. The cover lens structure of claim 1, further comprising a second segment height protruding from the first segment height wherein the second segment height and the first segment height form a second receiving space to allow the second segment height to retain the display panel.

4. The cover lens structure of claim 3, wherein the second segment height further comprises a second end-surface adjacent to the second receiving space for contacting the backlight module.

5. The cover lens structure of claim 3, wherein the first segment height and the second segment height are selected from one group consisting of a rectangular shape, a square shape, and an irregular shape.

6. The cover lens structure of claim 1, wherein the side-wall portion further comprises a position extrusion from an edge of the side-wall portion for locating the backlight module.

7. A touch display apparatus, comprising:
a touch sensing layer;
a display panel adjacent to the touch sensing layer;
a backlight module adjacent to the display panel; and
a cover lens structure, comprising:
a substrate;
a first segment height protruding from the substrate wherein the first segment height and the substrate forms a first receiving space to allow the first segment height to retain the touch sensing layer; and
a side-wall portion extending and bending from a side edge of the substrate wherein the side-wall portion has a locking portion for buckling the backlight module.

8. The touch display apparatus of claim 7, wherein the first segment height further comprises a first end-surface adjacent to the first receiving space for contacting the display panel.

9. The touch display apparatus of claim 7, further comprising a second segment height protruding from the first segment height wherein the second segment height and the first segment height form a second receiving space to allow the second segment height to retain the display panel.

10. The touch display apparatus of claim 9, wherein the second segment height further comprises a second end-surface adjacent to the second receiving space for contacting the backlight module.

11. The touch display apparatus of claim 9, wherein the first segment height and the second segment height are selected from one group consisting of a rectangular shape, a square shape, and an irregular shape.

12. The touch display apparatus of claim 7, wherein the side-wall portion further comprises a position extrusion from an edge of the side-wall portion for locating the backlight module.
